(19) United States
(12) Patent Application Publication
(10) Pub. No.: US 2016/0286698 A1
(43) Pub. Date: Sep. 29, 2016

(54) ELECTROMAGNETIC SHIELDING FILM AND CIRCUIT BOARD WITH ELECTROMAGNETIC SHIELDING FUNCTION

(71) Applicant: TAIFLEX Scientific Co., Ltd., Kaohsiung (TW)

(72) Inventors: Hsiu-Ming Chang, KAOHSIUNG (TW); Po-Wen Lin, KAOHSIUNG (TW); Ching-Wen Yu, KAOHSIUNG (TW)

(21) Appl. No.: 14/714,338

(22) Filed: May 17, 2015

(30) Foreign Application Priority Data
Mar. 27, 2015 (TW) 104110088

(51) Int. Cl. H05K 9/00; H05K 1/02; B32B 27/18; B32B 27/06; B32B 27/38

(52) U.S. Cl. CPC H05K 9/0083; B32B 27/06; B32B 27/38; B32B 27/18; H05K 1/0216; B32B 2250/02; B32B 2264/105; B32B 2307/206; B32B 2307/212; B32B 2457/08

(57) ABSTRACT

An electromagnetic shielding film includes an insulation layer, and an electromagnetic shielding layer arranged at one side of the insulation layer. The electromagnetic shielding layer includes a polymer substrate and an electromagnetic shielding material. The polymer substrate has epoxy structures. The electromagnetic shielding material has a plurality of aculeate electromagnetic shielding microparticles dispersed in the polymer substrate.

### BACKGROUND OF THE INVENTION

1. Field of the Invention

The present invention relates to an electromagnetic shielding film and a circuit board with electromagnetic shielding function, and more particularly, to an electromagnetic shielding film and a circuit board with electromagnetic shielding function capable of increasing product stability and improving electromagnetic shielding efficiency.

2. Description of the Prior Art

Please refer to FIG. 1. FIG. 1 is a diagram showing an electromagnetic shielding film of the prior art. As shown in FIG. 1, the electromagnetic shielding film 100 of the prior art comprises a protective film 110, a conductive adhesive layer 120, an insulation layer 130 and a release film 140. A metal layer 122 is formed on the conductive adhesive layer 120. When using the electromagnetic shielding film 100 of the prior art, the protective film 110 is removed before attaching the conductive adhesive layer 120 to a circuit board, and then the release film 140 is removed before performing hot pressing. In the electromagnetic shielding film 100 of the prior art, the metal layer 122 is utilized to suppress electromagnetic interference between circuit boards during signal transmission. In addition, in order to reduce cost of the electromagnetic shielding film of the prior art, the metal layer 122 may be omitted, and metal powders can be added into the conductive adhesive layer 120. However, the electromagnetic shielding film added with the metal powders has poor electromagnetic shielding efficiency and flexibility. At this point, the amount or shape of the metal powders may affect characteristics of the material.

In the aforementioned two electromagnetic shielding films of the prior art, the conductive adhesive layer 120 and the insulation layer 130 are mainly made of a polyurethane resin. However, a disadvantage of the polyurethane resin is having insufficient heat resistance (resistant to a temperature about 260° C.), such that the electromagnetic shielding films of the prior art are unable to bear higher temperature (such as a welding temperature above 288° C.) when the circuit board is under welding and back-end high temperature processes. Although the prior art has developed a material to increase heat resistance of the electromagnetic shielding film by mixing polyurethane and epoxy acrylate, reaction of the epoxy acrylate and metal ions may shorten storage time. Moreover, the conductive adhesive layer 120 of the prior art is adhesive at room temperature, and the protective film 110 is required to be attached thereon for preventing the conductive adhesive layer 120 from being attached with foreign bodies. Therefore, structure of the electromagnetic shielding film of the prior art is more complex, so as to further reduced assembly efficiency of the circuit board.

### SUMMARY OF THE INVENTION

The present invention provides an electromagnetic shielding film and a circuit board with electromagnetic shielding function capable of increasing product stability and improving electromagnetic shielding efficiency, in order to solve problems of the prior art.

The electromagnetic shielding film of the present invention comprises an insulation layer and an electromagnetic shielding layer arranged at one side of the insulation layer. The electromagnetic shielding layer comprises a polymer substrate and an electromagnetic shielding material. The polymer substrate has epoxy structures. The electromagnetic shielding material has a plurality of aculeate electromagnetic shielding microparticles dispersed in the polymer substrate.

In an embodiment of the present invention, the aculeate electromagnetic shielding microparticle has a plurality of thorns, length of each of the thorns is between 1 μm and 15 μm, and width of each of the thorns is between 0.1 μm and 5 μm.

In an embodiment of the present invention, the plurality of aculeate electromagnetic shielding microparticles are mutually contacted to form a three-dimensional electromagnetic shielding network in the polymer substrate.

In an embodiment of the present invention, the aculeate electromagnetic shielding microparticle comprises an aculeate metal particle and an antioxidant layer covered on a surface of the aculeate metal particle.

In an embodiment of the present invention, the aculeate metal particle is made of a material selected from a group consisting of copper, nickel, iron, lead, and zinc, the antioxidant layer is made of a material selected from a group consisting of silver, chrome, nickel, graphene, copper oxide, an alloy material, and a gas barrier polymer material.

In an embodiment of the present invention, the polymer substrate is formed by mixing epoxy monomers with biphenyl, naphthyl or anthryl groups and rubber with acid groups.

In an embodiment of the present invention, a weight ratio of rubber with acid groups to the epoxy monomers with biphenyl, naphthyl or anthryl groups is between 0.1 and 0.5.

In an embodiment of the present invention, a weight ratio of the electromagnetic shielding material to the polymer substrate is between 0.5 and 2.

In an embodiment of the present invention, a concentration of chloride ions in the polymer substrate is between 100 ppm and 2000 ppm.

In an embodiment of the present invention, the concentration of chloride ions in the polymer substrate is below 500 ppm.

In an embodiment of the present invention, the electromagnetic shielding film further comprises a release film connected to another side of the insulation layer.

The circuit board with electromagnetic shielding function of the present invention comprises a base plate, a metal wire, a cover film and an electromagnetic shielding film. The metal wire is formed on the base plate. The cover film is covered on the metal wire and the base plate, and the electromagnetic shielding film is covered on the cover film. The electromagnetic shielding film comprises an insulation layer and an electromagnetic shielding layer. The electromagnetic shielding layer has a first surface arranged at one side of the insulation layer and a second surface connected to the cover film. The electromagnetic shielding layer comprises a polymer resin substrate and an electromagnetic shielding material. The polymer resin substrate is made of a polymer resin with epoxy groups and the electromagnetic shielding material has a plurality of aculeate electromagnetic shielding microparticles dispersed in the polymer resin substrate.

In contrast to the prior art, the electromagnetic shielding film of the present invention is formed by mixing the epoxy monomers with biphenyl, naphthyl or anthryl groups and rubber with acid groups, in order to improve heat resistance and storage time of the electromagnetic shielding film. Electromagnetic shielding efficiency of the electromagnetic shielding film of the present invention is increased through the three-dimensional electromagnetic shielding network formed by the aculeate electromagnetic shielding microparticles. Moreover, the electromagnetic shielding film of the present invention is not adhesive under room temperature, thus a protective film is not required, so as to simplify structure of the electromagnetic shielding film of the present invention and increase assembly efficiency of the circuit board.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing an electromagnetic shielding film of the prior art.

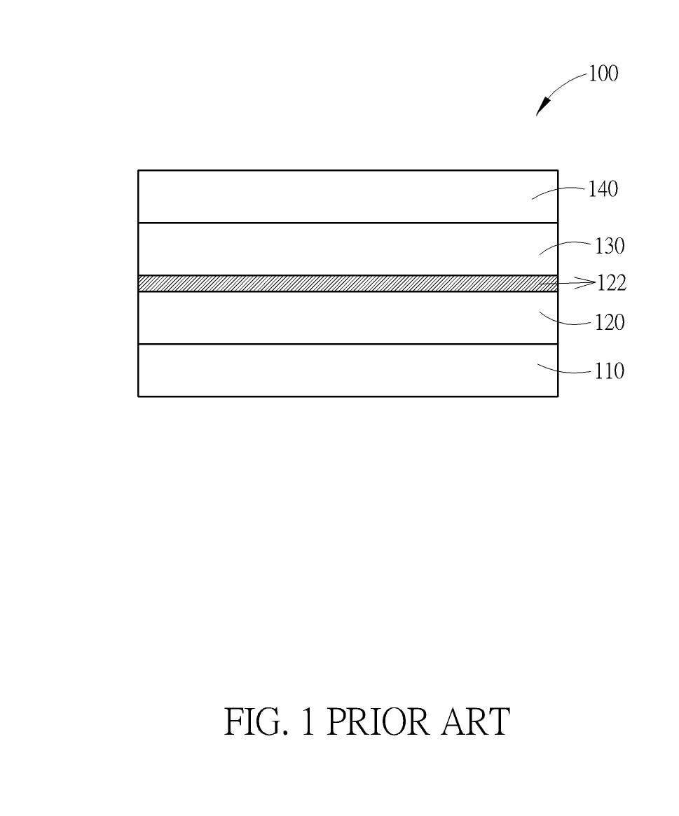

FIG. 2 is a diagram showing an electromagnetic shielding film of the present invention.

FIG. 3 is a diagram showing an aculeate electromagnetic shielding microparticle of the present invention.

FIG. 4 is a diagram showing a three-dimensional electromagnetic shielding network formed by the aculeate electromagnetic shielding microparticles of the present invention.

FIG. 5 is a diagram showing a structure of an epoxy monomer with naphthyl groups in the polymer substrate of the present invention.

FIG. 6 is a diagram showing a circuit board with electromagnetic shielding function according to an embodiment of the present invention.

FIG. 7 is a diagram showing a circuit board with electromagnetic shielding function according to another embodiment of the present invention.

### DETAILED DESCRIPTION

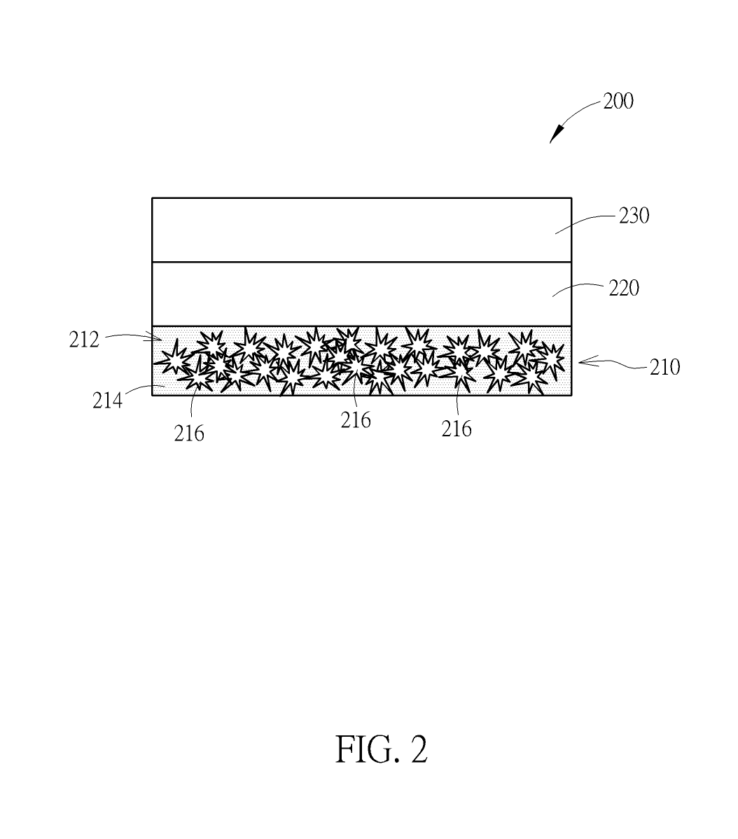

Please refer to FIG. 2. FIG. 2 is a diagram showing an electromagnetic shielding film of the present invention. As shown in FIG. 2, the electromagnetic shielding film 200 of the present invention comprises an insulation layer 220 and an electromagnetic shielding layer 210. The electromagnetic shielding layer 210 is arranged at one side of the insulation layer 220. The electromagnetic shielding film 200 can further comprise a release film 230 connected to another side of the insulation layer 220. The electromagnetic shielding layer 210 comprises a polymer substrate 214 and an electromagnetic shielding material 212. The electromagnetic shielding material 212 has a plurality of aculeate electromagnetic shielding microparticles 216 evenly dispersed in the polymer substrate 214.

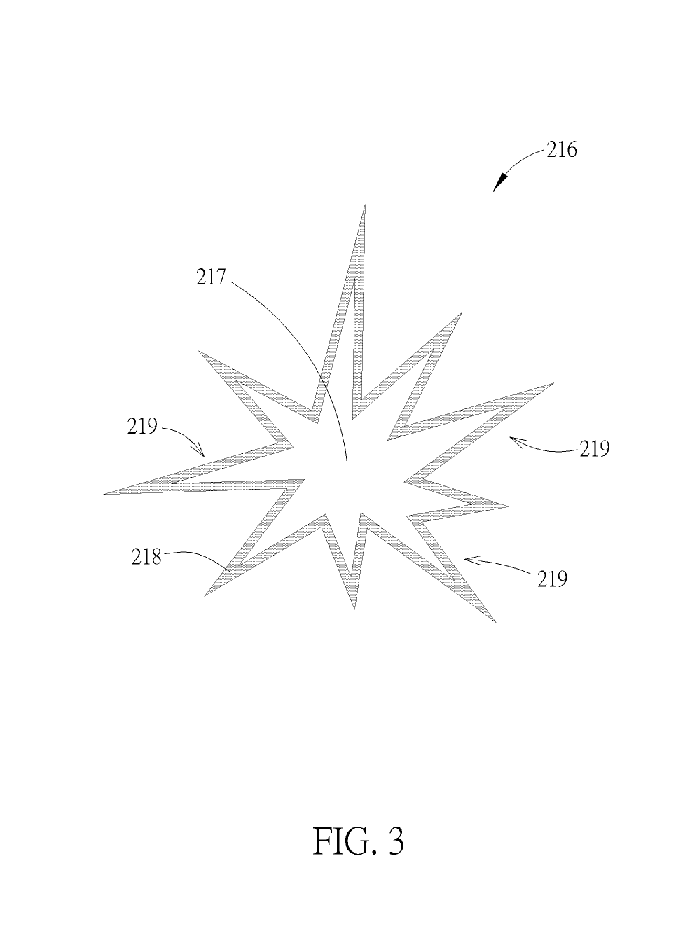

Please refer to FIG. 3. FIG. 3 is a diagram showing an aculeate electromagnetic shielding microparticle of the present invention. As shown in FIG. 3, the aculeate electromagnetic shielding microparticle 216 of the present invention comprises an aculeate metal particle 217 and an antioxidant layer 218. The antioxidant layer 218 is covered on a surface of the aculeate metal particle 217. The aculeate electromagnetic shielding microparticle 216 has a plurality of thorns 219. Length of each of the thorns 219 is between 1 μm and 15 μm, and width of each of the thorns 219 is between 0.1 μm and 5 μm. The aculeate metal particle 217 is made of a material selected from a group consisting of copper, nickel, iron, lead, and zinc, and the antioxidant layer 218 is made of a material selected from a group consisting of silver, chrome, nickel, graphene, copper oxide, an alloy material, and a gas barrier polymer material, but the present invention is not limited thereto. Wherein, the gas barrier polymer material is made of a material selected from a group consisting of an ultraviolet (UV) sensitive epoxy acrylate resin, and an UV sensitive polyurethane acrylate resin (with 2 to 12 double bonds), but the present invention is not limited thereto. The aculeate metal particle 217 can also be made of other metals with higher antioxidant ability, for example, gold, silver, and nickel. In other embodiments of the present invention, when the aculeate metal particle 217 is made of the metal with higher antioxidant ability, the aculeate electromagnetic shielding microparticle 216 can be formed without the antioxidant layer 218. In an embodiment of the present invention, the aculeate metal particle 217 is made of copper, the antioxidant layer 218 is made of silver covering on the aculeate metal particle 217, and a weight percentage of silver in the aculeate electromagnetic shielding microparticle 216 is between 1% and 12%.

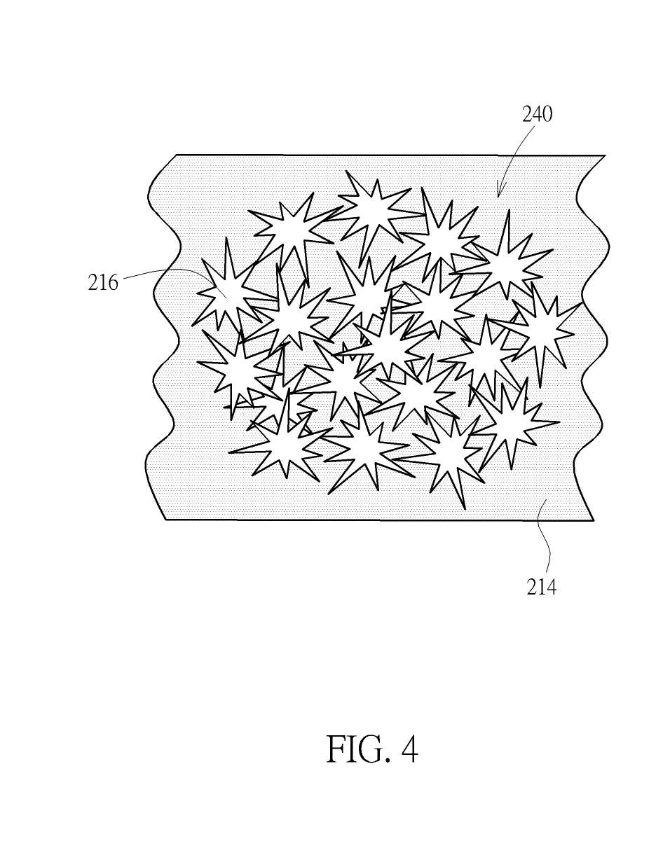

Please refer to FIG. 4. FIG. 4 is a diagram showing a three-dimensional electromagnetic shielding network formed by the aculeate electromagnetic shielding microparticles of the present invention. As shown in FIG. 4, the plurality of aculeate electromagnetic shielding microparticles 216 are mutually contacted to form a continuous three-dimensional electromagnetic shielding network 240 in the polymer substrate 214. Wherein, the polymer substrate 214 is filled in the gap between the aculeate electromagnetic shielding microparticles 216.

According to the above arrangement, in the electromagnetic shielding layer 210, the plurality of aculeate electromagnetic shielding microparticles 216 are mutually contacted to form the three-dimensional electromagnetic shielding network 240, such that overall resistance of the plurality of aculeate electromagnetic shielding microparticles 216 is decreased and electromagnetic shielding efficiency of the electromagnetic shielding film 200 is increased. In an embodiment of the present invention, the electromagnetic shielding layer 210 is formed by mixing 1 gram of the epoxy monomers 300, 1.5 grams of rubber with acid groups, and 4.5 grams of the electromagnetic shielding material 212. Wherein, a weight ratio of silver to copper in the aculeate electromagnetic shielding microparticle 216 is about 0.1. When coating the aforementioned ingredients to form an electromagnetic shielding layer with a thickness of 15 μm, electromagnetic shielding efficiency of the formed electromagnetic shielding film is 50 dB. Comparing to the electromagnetic shielding film of the prior art with electromagnetic shielding efficiency of about 45 dB (the electromagnetic shielding layer of the prior art has a thickness of 15 μm), electromagnetic shielding efficiency of the electromagnetic shielding film 200 of the present invention is better.

In addition, when the electromagnetic shielding layer of the present invention has a thickness of 10 μm, the electromagnetic shielding efficiency of the formed electromagnetic shielding film is 40 dB. When the electromagnetic shielding layer of the present invention has a thickness of 20 μm, the electromagnetic shielding efficiency of the formed electromagnetic shielding film is 60 dB. With the same thickness, the electromagnetic shielding efficiency of the electromagnetic shielding film of the present invention is better than that of the electromagnetic shielding film of the prior art.

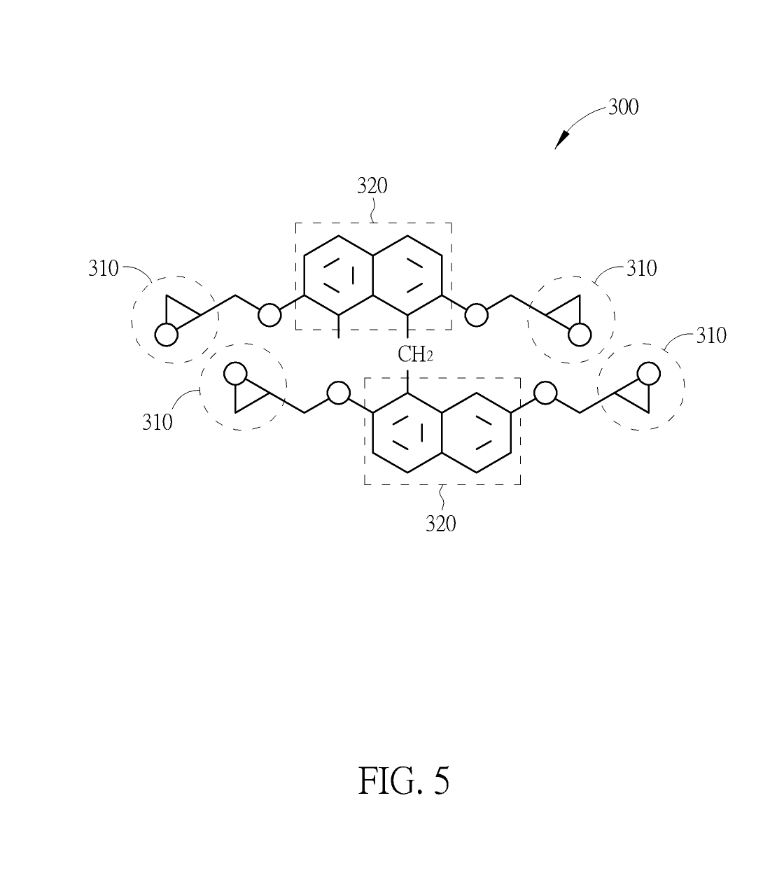

On the other hand, the polymer substrate 214 of the present invention is formed by mixing the epoxy monomers with naphthyl groups and the rubber with acid groups. Please refer to FIG. 5. FIG. 5 is a diagram showing a structure of an epoxy monomer with naphthyl groups in the polymer substrate of the present invention. As shown in FIG. 5, the epoxy monomer 300 has four epoxy groups 310 and two naphthyl groups 320. Wherein, the epoxy groups 310 can increase heat resistance of the electromagnetic shielding film 200 and is also utilized for crosslinking reaction with the rubber with acid groups through a thermal process. The naphthyl groups 320 can also increase heat resistance of the electromagnetic shielding film 200. The naphthyl groups in the epoxy monomer 300 of the present invention can also be replaced by biphenyl or anthryl groups. Moreover, the rubber with acid groups can be a polyester acrylic resin with molecular weight between 5000 and 500000 containing 10 to 36 carbons, but the present invention is not limited thereto. The rubber with acid groups can increase flexibility of the polymer substrate 214. A concentration of chloride ions in the polymer substrate 214 of the present invention is between 100 ppm and 2000 ppm. The concentration of chloride ions is preferably to be below 500 ppm in order to decrease reactivity of the electromagnetic shielding film 200 when being catalyzed by metal ions, so as to further extend storage time of the electromagnetic shielding film 200. Moreover, the polymer substrate 214 of the present invention is not adhesive at room temperature, such that the protective film is not required to prevent the electromagnetic shielding film from being attached with foreign bodies. The polymer substrate 214 of the present invention is adhesive only after crosslinking the epoxy monomers with biphenyl, naphthyl or anthryl groups and the rubber with acid groups at high temperature.

In an embodiment of the present invention, the insulation layer 220 and the electromagnetic shielding layer 210 of the electromagnetic shielding film 200 of the present invention are formed by mixing the aforementioned epoxy monomers 300 and rubber with acid groups followed by performing the thermal process for crosslinking reaction. In a comparative example, the insulation layer and the electromagnetic shielding layer of the electromagnetic shielding film of the comparative example are made of a polyurethane resin. Through actual measurements, a thermal decomposition temperature of the electromagnetic shielding film of the present invention is 360° C., and a thermal decomposition temperature of the electromagnetic shielding film of the comparative example is 290° C. Therefore, the electromagnetic shielding film of the present invention has better heat resistance. In addition, the electromagnetic shielding film of the present invention can undergo an 180-degree bending test at least 16 times, and the electromagnetic shielding film of the comparative example can undergo the 180-degree bending test only 10 times. Therefore, the electromagnetic shielding film of the present invention has better flexibility. Moreover, the electromagnetic shielding film of the present invention can be stored for 20 hours under 90° C., and the electromagnetic shielding film of the comparative example can be stored for about 15 hours under 90° C. Therefore, the electromagnetic shielding film of the present invention has longer storage time.

According to the above arrangement, the epoxy monomers with biphenyl, naphthyl or anthryl groups can increase heat resistance of the polymer substrate 214, in order to solve the problem of the electromagnetic shielding film of the prior art having insufficient heat resistance. Moreover, the polymer substrate 214 of the present invention has a lower chloride ions concentration, so as to increase stability of the electromagnetic shielding film 200, and solve the problem of the electromagnetic shielding film of the prior art having a shorter storage time.

In the aforementioned embodiment, a weight ratio of the electromagnetic shielding material 212 to the polymer substrate 214 is between 0.5 and 2, and a weight ratio of the rubber with acid groups to the epoxy monomers with biphenyl, naphthyl or anthryl groups is between 0.1 and 0.5, but the present invention is not limited thereto. In an embodiment of the present invention, the weight ratio of the electromagnetic shielding material 212 to the polymer substrate 214 is preferably to be 2, and the weight ratio of the rubber with acid groups to the epoxy monomers with biphenyl, naphthyl or anthryl groups is preferably to be 0.5.

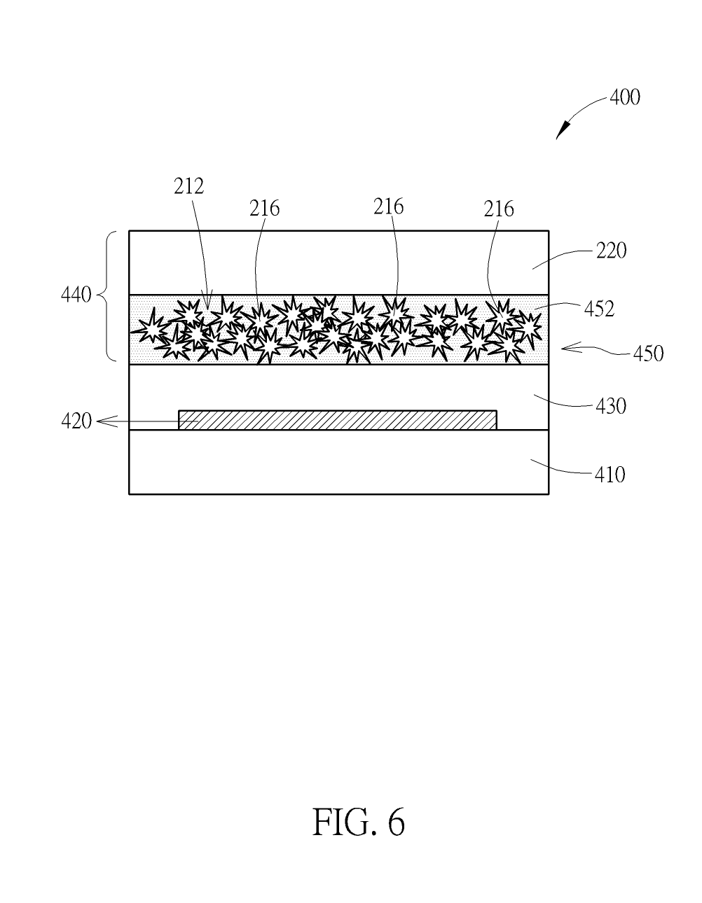

Please refer to FIG. 6. FIG. 6 is a diagram showing a circuit board with electromagnetic shielding function according to an embodiment of the present invention. As shown in FIG. 6, the circuit board with electromagnetic shielding function 400 of the present invention comprises a base plate 410, a metal wire 420, a cover film 430 and an electromagnetic shielding film 440. The metal wire 420 is formed on the base plate 410. In the present embodiment, the metal wire 420 is utilized to transmit electronic signals. The cover film 430 is covered on the metal wire 420 and the base plate 410, and the electromagnetic shielding film 440 is formed by covering the electromagnetic shielding film 200 of FIG. 2 on the cover film 430, and removing the release film 230 to go through the thermal process. The electromagnetic shielding film 440 comprises an insulation layer 220 and an electromagnetic shielding layer 450. An upper surface of the electromagnetic shielding layer 450 is arranged at one side of the insulation layer 220, and a lower surface of the electromagnetic shielding layer 450 is connected to the cover film 430. After the thermal process, the epoxy monomers with biphenyl, naphthyl or anthryl groups and the rubber with acid groups in the electromagnetic shielding layer 450 react to crosslink for forming a polymer resin substrate 452, so as to adhere and fix the electromagnetic shielding layer 450 to the cover film 430. The polymer resin substrate 452 contains epoxy groups, in other words, the polymer resin substrate 452 is made of the polymer resin with epoxy groups.

According to the above arrangement, the electromagnetic shielding film 440 of the present invention has better heat resistance and longer storage time. Moreover, the plurality of aculeate electromagnetic shielding microparticles 216 can be mutually contacted to form the continuous three-dimensional electromagnetic shielding network in the electromagnetic shielding layer 450, so as to further increase electromagnetic shielding efficiency of the circuit board.

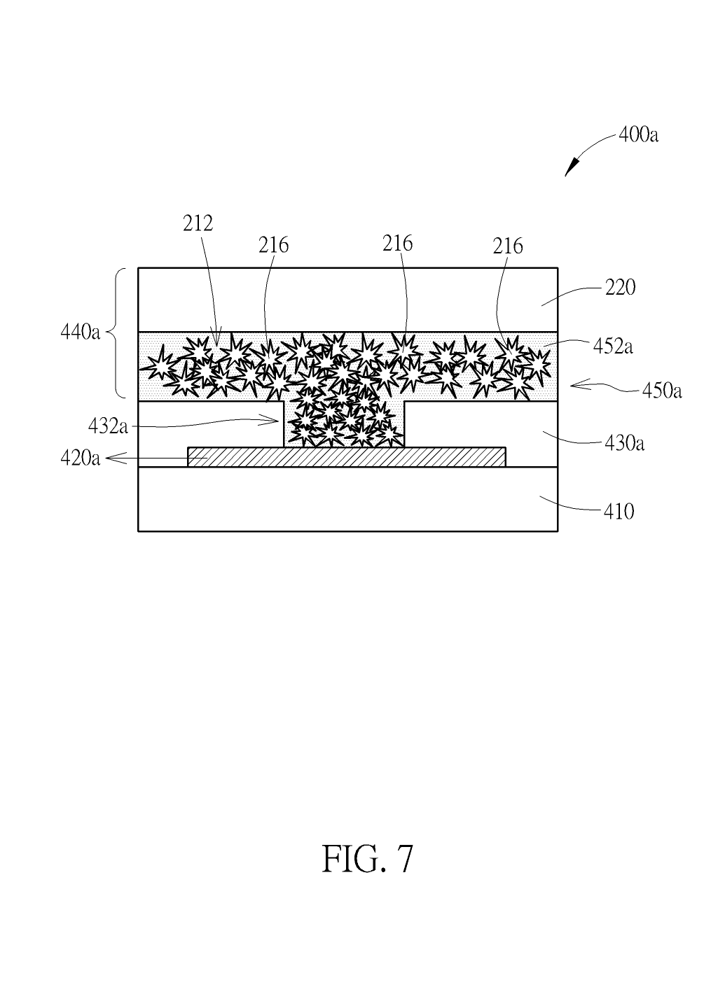

Please refer to FIG. 7. FIG. 7 is a diagram showing a circuit board with electromagnetic shielding function according to another embodiment of the present invention. As shown in FIG. 7, the circuit board with electromagnetic shielding function 400a of the present invention comprises a base plate 410, a metal wire 420a, a cover film 430a and an electromagnetic shielding film 440a. The metal wire 420a is formed on the base plate 410. In the present embodiment, the metal wire 420a is electrically connected to a ground terminal. The cover film 430a is covered on the metal wire 420a and the base plate 410, and an opening 432a is formed on the cover film 430a. The electromagnetic shielding film 440a is formed by covering the electromagnetic shielding film 200 of FIG. 2 on the cover film 430a, and removing the release film 230 to go through the thermal process. The electromagnetic shielding film 440a comprises an insulation layer 220 and an electromagnetic shielding layer 450a. An upper surface of the electromagnetic shielding layer 450a is arranged at one side of the insulation layer 220, and a lower surface of the electromagnetic shielding layer 450a is connected to the cover film 430a. After the thermal process, the epoxy monomers with biphenyl, naphthyl or anthryl groups and the rubber with acid groups in the electromagnetic shielding layer 450a react to crosslink for forming a polymer resin substrate 452a, so as to adhere and fix the electromagnetic shielding layer 450a to the cover film 430a. Moreover, a part of the electromagnetic shielding layer 450a is filled in the opening 432a to contact with the metal wire 420a.

According to the above arrangement, since the metal wire 420a is electrically connected to the ground terminal, and the plurality of aculeate electromagnetic shielding microparticles 216 in the electromagnetic shielding layer 450a contacts the metal wire 420a, energy absorbed by the electromagnetic shielding layer 450a when providing the electromagnetic shielding function can be guided and transmitted to the ground terminal, so as to increase electromagnetic shielding efficiency of the circuit board.

In addition, in the embodiment of the present invention, the electromagnetic shielding layer only contacts the metal wire electrically connected to the ground terminal. The electromagnetic shielding layer does not contact the metal wire transmitting electronic signals in order to prevent the metal wire transmitting electronic signals from being short circuited.

In contrast to the prior art, the electromagnetic shielding film of the present invention is formed by mixing the epoxy monomers with biphenyl, naphthyl or anthryl groups and rubber with acid groups, in order to improve heat resistance and storage time of the electromagnetic shielding film. Electromagnetic shielding efficiency of the electromagnetic shielding film of the present invention is increased through the three-dimensional electromagnetic shielding network formed by the aculeate electromagnetic shielding microparticles. Besides, the electromagnetic shielding film of the present invention is not adhesive under room temperature, thus a protective film is not required, so as to simplify structure of the electromagnetic shielding film of the present invention and increase assembly efficiency of the circuit board.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electromagnetic shielding film, comprising:
an insulation layer; and
an electromagnetic shielding layer, arranged at one side of the insulation layer, the electromagnetic shielding layer comprising:
a polymer substrate, having epoxy structures; and
an electromagnetic shielding material, having a plurality of aculeate electromagnetic shielding microparticles dispersed in the polymer substrate.

2. The electromagnetic shielding film of claim 1, wherein the aculeate electromagnetic shielding microparticle has a plurality of thorns, length of each of the thorns is between 1 μm and 15 μm, width of each of the thorns is between 0.1 μm and 5 μm.

3. The electromagnetic shielding film of claim 1, wherein the plurality of aculeate electromagnetic shielding microparticles are mutually contacted to form a three-dimensional electromagnetic shielding network in the polymer substrate.

4. The electromagnetic shielding film of claim 1, wherein the aculeate electromagnetic shielding microparticle comprises:
an aculeate metal particle; and
an antioxidant layer, covered on a surface of the aculeate metal particle.

5. The electromagnetic shielding film of claim 4, wherein the aculeate metal particle is made of copper, the antioxidant layer is made of a material selected from a group consisting of silver, chrome, nickel, graphene, copper oxide, an alloy material, and a gas barrier polymer material.

6. The electromagnetic shielding film of claim 1, wherein the polymer substrate is formed by mixing epoxy monomers with biphenyl, naphthyl or anthryl groups and rubber with acid groups.

7. The electromagnetic shielding film of claim 6, wherein a weight ratio of rubber with acid groups to the epoxy monomers with biphenyl, naphthyl or anthryl groups is between 0.1 and 0.5.

8. The electromagnetic shielding film of claim 1, wherein a weight ratio of the electromagnetic shielding material to the polymer substrate is between 0.5 and 2.

9. The electromagnetic shielding film of claim 1, wherein a concentration of chloride ions in the polymer substrate is between 100 ppm and 2000 ppm.

10. The electromagnetic shielding film of claim 9, wherein the concentration of chloride ions in the polymer substrate is below 500 ppm.

11. The electromagnetic shielding film of claim 1 further comprising
a release film connected to another side of the insulation layer.

12. A circuit board with electromagnetic shielding function, comprising:
a base plate;
a metal wire, formed on the base plate;
a cover film, covered on the metal wire and the base plate; and
an electromagnetic shielding film, covered on the cover film, the electromagnetic shielding film comprising:
an insulation layer; and
an electromagnetic shielding layer, having a first surface arranged at one side of the insulation layer and a second surface connected to the cover film, the electromagnetic shielding layer comprising:
a polymer resin substrate, made of a polymer resin with epoxy groups; and
an electromagnetic shielding material, having a plurality of aculeate electromagnetic shielding microparticles dispersed in the polymer resin substrate.

13. The circuit board of claim 12, wherein the aculeate electromagnetic shielding microparticle has a plurality of thorns, length of each of the thorns is between 1 μm and 15 μm, width of each of the thorns is between 0.1 μm and 5 μm.

14. The circuit board of claim 12, wherein the plurality of aculeate electromagnetic shielding microparticles are mutually contacted to form a three-dimensional electromagnetic shielding network in the polymer resin substrate.

15. The circuit board of claim 12, wherein the aculeate electromagnetic shielding microparticle comprises:
an aculeate metal particle; and
an antioxidant layer, covered on a surface of the aculeate metal particle.

16. The circuit board of claim 15, wherein the aculeate metal particle is made of copper, the antioxidant layer is made of a material selected from a group consisting of silver, chrome, nickel, graphene, copper oxide, an alloy material, and a gas barrier polymer material.

17. The circuit board of claim 12, wherein the polymer resin substrate is formed by crosslinking the epoxy monomers with biphenyl, naphthyl or anthryl groups and rubber with acid groups through a thermal process.

18. The circuit board of claim 17, wherein a weight ratio of rubber with acid groups to the epoxy monomers with biphenyl, naphthyl or anthryl groups is between 0.1 and 0.5.

19. The circuit board of claim 12, wherein a weight ratio of the electromagnetic shielding material to the polymer resin substrate is between 0.5 and 2.

20. The circuit board of claim 12, wherein a concentration of chloride ions in the polymer resin substrate is between 100 ppm and 2000 ppm.

21. The circuit board of claim 20, wherein the concentration of chloride ions in the polymer resin substrate is below 500 ppm.
